(19) United States
(12) Patent Application Publication
(10) Pub. No.: US 2026/0305064 A1
(43) Pub. Date: Oct. 1, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Jeonghaeng HEO, Beijing (CN); Mengqi JIANG, Beijing (CN)

(21) Appl. No.: 19/475,359

(22) PCT Filed: Sep. 3, 2024
(86) PCT No.: PCT/CN2024/116520

§ 371 Date: Oct. 14, 2025

(30) Foreign Application Priority Data
Oct. 18, 2023 (CN) 202311355403.3

(51) Int. Cl. H10K 50/15; H10K 50/155; H10K 102/00

(52) U.S. Cl. CPC H10K 50/156; H10K 50/155; H10K 2102/351

(57) ABSTRACT

A display panel includes a first electrode, a first hole transport layer, a light-emitting layer, and a second electrode which are sequentially stacked on a substrate in a first direction. The light-emitting layer includes a first light-emitting region, a second light-emitting region and a third light-emitting region, which are arranged in a second direction and emit different colors of light. The first hole transport layer includes a first hole transport region opposite to the first light-emitting region and the second light-emitting region, and a second hole transport region opposite to the third light-emitting region. The first hole transport region of the first hole transport layer is formed of a hole matrix and a first p-type doping material.

### TECHNICAL FIELD

The present application relates to the field of display technology, and specifically relates to a display panel and a display device.

### BACKGROUND

The organic electroluminescent display (OLED) devices are widely used due to their advantages of self-luminescence, wide color gamut, low power consumption, flexible display, and the like. In the related art, an OLED may be driven at a low voltage to implement low current operation. However, in the low current operation mode, the display panel tends to have color abnormality due to lateral electric leakage, and especially after reliability testing, and particularly, different brightnesses of RGB is likely to occur, causing a color cast.

### SUMMARY

In view of the defects in the related art, the present application proposes a display panel and a display device which can solve the problem of the color cast of the display panel in the related art.

The present application provides a display panel, including a first electrode, a first hole transport layer, a light-emitting layer, and a second electrode which are sequentially stacked on a substrate in a first direction, wherein the first direction is a direction pointing to the second electrode from the first electrode, and a second direction is perpendicular to the first direction; wherein the light-emitting layer includes a first light-emitting region, a second light-emitting region and a third light-emitting region, which are arranged in the second direction and emit different colors of light; and the first hole transport layer includes a first hole transport region opposite to the first light-emitting region and the second light-emitting region, and a second hole transport region opposite to the third light-emitting region; and the first hole transport region of the first hole transport layer is formed of a hole matrix and a first p-type doping material.

In this embodiment, regions of the display panel corresponding to the first light-emitting region and the second light-emitting region are p-type doped, while the remaining regions are not doped, so that an overall capacitance of the first light-emitting region and the second light-emitting region can be adjusted to keep the capacitance of the first light-emitting region and the capacitance of the second light-emitting region in the light-emitting layer at the same level, thereby alleviating the problem of the color cast of the display panel after reliability testing.

In one embodiment, a mass percent of the first p-type doping material in the first hole transport region of the first hole transport layer is greater than or equal to 0.1% and less than or equal to 1%.

In one embodiment, the first hole transport region of the first hole transport layer includes a first hole transport sub-layer and a second hole transport sub-layer sequentially stacked in the first direction, wherein the first hole transport sub-layer is formed of the hole matrix and the first p-type doping material; and the second hole transport sub-layer is formed of the hole matrix.

In one embodiment, a ratio of a thickness of the first hole transport sub-layer in the first direction to a thickness of the second hole transport sub-layer in the first direction is in a range of 1:3 to 1:10.

In one embodiment, the display panel further includes a second hole transport layer on a side of the first hole transport layer away from the light-emitting layer; and a ratio of a thickness of the first hole transport layer in the first direction to a thickness of the second hole transport layer in the first direction is in a range of 1:1 to 1:4.

In one embodiment, wavelengths of light emitted from the first light-emitting region, the second light-emitting region, and the third light-emitting region sequentially decrease; and in the first direction, thicknesses of the first light-emitting region, the second light-emitting region and the third light-emitting region of the light-emitting layer sequentially decrease.

In one embodiment, a hole injection layer, formed of the hole matrix and a second p-type doping material, is further provided on a side of the first electrode away from the substrate.

In one embodiment, a mass percent of the second p-type doping material in the hole injection layer is greater than or equal to 1% and less than or equal to 10%.

In one embodiment, the first p-type doping material includes 2,3,5,6-tetrafluoro-7,7′,8,8′-tetracyanodimethyl-p-benzoquinone, 2,3,6,7,10,11-hexacyano-1,4,5,8,9,12-hexaazatriphenylene, or pyrazolo[2,3-F][1,10]phenanthroline-2,3-dinitrile.

In one embodiment, the hole matrix includes N,N′-diphenyl-N,N′-(1-naphthyl)-1,1′-biphenyl-4,4′-diamine, N,N′-diphenyl-N,N′-bis(3-methylphenyl)-[1,1′-biphenyl]-4,4′-diamine, 4,4′,4″-tris(carbazole-9-yl)triphenylamine (TCTA), or 4-[1-[4-[bis(4-methylphenyl)amino]phenyl]cyclohexyl]-N-(3-methylphenyl)-N-(4-methylphenyl) aniline.

The present application further provides a display device, including the display panel as described above.

Additional aspects and advantages of the present application will be set forth in part and become apparent in the description below, or may be learned by practice of the present application.

### BRIEF DESCRIPTION OF FIGURES

The accompanying drawings, which are incorporated in and constitute a part of this specification, illustrate embodiments consistent with the present application and, together with the description, serve to explain the principles of the present application.

FIG. 1 is a cross-sectional view of a display panel in the related art;

FIG. 2 is a cross-sectional view of a display panel according to an embodiment of the present application;

FIG. 3 is a cross-sectional view of another display panel according to an embodiment of the present application;

FIG. 4 is a cross-sectional view of yet another display panel according to an embodiment of the present application; and

FIG. 5 is a comparison diagram between test results of a display panel in the related art and a display panel according to an embodiment of the present application.

In the drawings: 1—substrate; 2—first electrode; 3—hole injection layer; 4—second hole transport layer; 5′—first original hole transport layer; 5a′—first original hole transport region; 5b′—second original hole transport region; 5c′—third original hole transport region; 5—first hole transport layer; 5ab—first hole transport region; 5ab1—first hole transport sub-layer; 5ab11—first hole transport sub-region; 5ab12—second hole transport sub-region; 5ab2—second hole transport sub-layer; 5ab3—third hole transport sub-layer; 5c—second hole transport region; 6—light-emitting layer; 6a—first light-emitting region; 6b—second light-emitting region; 6c—third light-emitting region; 7—hole blocking layer; 8—electron transport layer; 9—electron injection layer; 10—second electrode; and 11—encapsulation layer.

### DETAILED DESCRIPTION

Here, exemplary embodiments will be illustrated in detail, examples of which are shown in the accompanying drawings. The following description refers to the accompanying drawings in which the same numbers in different drawings represent the same or similar elements unless otherwise indicated. The embodiments described in the following exemplary embodiments do not represent all embodiments consistent with the present application. Rather, they are merely examples of devices and methods consistent with certain aspects of the present application, as detailed in the appended claims.

The terminology used in the present application is for the purpose of describing particular embodiments only, and is not intended to limit the present application. As used in the present application and the appended claims, the singular forms “a”, “an”, and “the” are intended to include the plural forms as well, unless the context clearly indicates otherwise. It should also be understood that the term “and/or” as used herein refers to and encompasses any and all possible combinations of one or more of the associated listed items.

It should be understood that when a layer or region is referred to as being “on” or “over” another layer or region in describing the structure of the element, it can be directly on the other layer or region, or intervening layers or regions may also be present. Also, if the component is turned over, one layer or region may be “under” or “beneath” another layer or region.

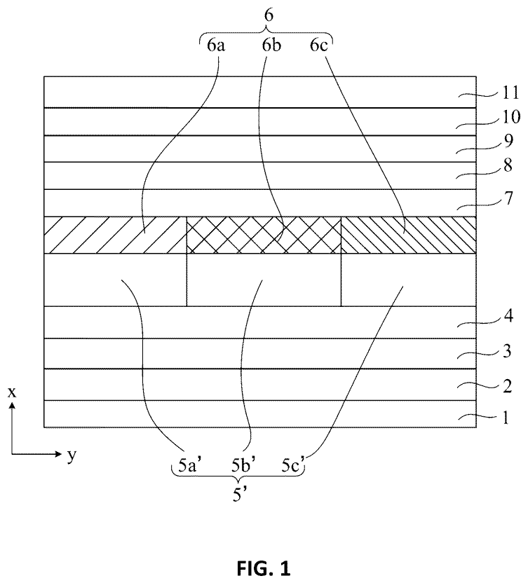

As shown in FIG. 1, the working principle of the display panel is as follows: in operation, a bias voltage is applied between a first electrode 2 and a second electrode 10 of the display panel so that holes and electrons break through an interface energy barrier and migrate from a hole transport layer and an electron transport layer 8 to a light-emitting layer 6 respectively, where the electrons and the holes are recombined to generate excitons, the excitons are not stable and release energy to molecules of a luminescent material in the light-emitting layer 6 to enable the molecules to jump from a ground state to an excited state. The excited state is not stable so that a radiative transition occurs when the excited molecules return to the ground state from the excited state, resulting in luminescence.

With the continuous update and iteration of the technology, the display panel can be driven at low voltage to implement low current operation. However, in the low current operation mode, the display panel tends to have a lateral electric leakage problem at a low brightness, and thus leads to an abnormal emission color. There are two main causes for the lateral electric leakage, one is a parasitic capacitance generated by a thin film transistor in the driver circuit, and the other is an interface between a doped hole injection layer 3 and a first electrode 2 on the display panel, which is not easy to avoid since the doped hole injection layer 3 can play a role in reducing the voltage and extending the display life. In addition, since the red subpixel and the green subpixel on the display panel have different materials for the hole transport layer and different materials for the light-emitting layer 6, the overall capacitances are also different. As a result, after the reliability testing, the capacitance of the green subpixel is reduced, and the charging amount is small, so more current is input, making the green subpixel brighter and leading to a color cast.

The present application provides a display panel and a display device which aim to solve the above technical problem in the related art.

The following describes the display panel and the display device in the embodiments of the present application in detail with reference to the accompanying drawings. The features of the embodiments described below may complement or be combined with each other without conflict.

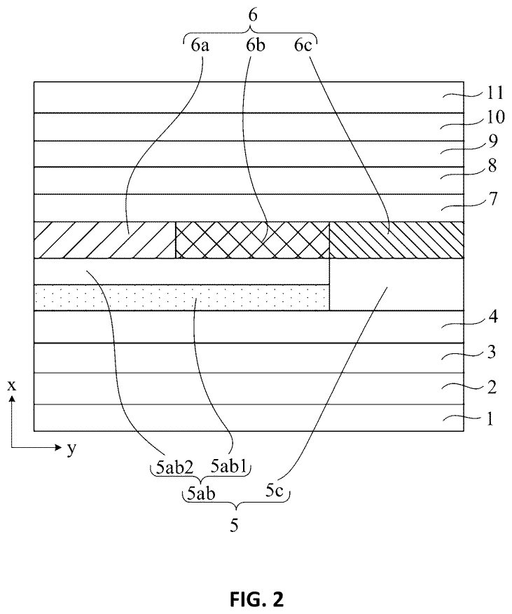

An embodiment of the present application provides a display panel which, as shown in FIG. 2, includes a first electrode 2, a first hole transport layer 5, a light-emitting layer 6, and a second electrode 10 which are sequentially stacked on a substrate 1 in a first direction x. The first direction x is a direction pointing to the second electrode 10 from the first electrode 2, and a second direction y is perpendicular to the first direction x.

It should be noted that the first direction x perpendicular to the second direction y means that the first direction x is substantially perpendicular to the second direction y, and an angle formed between the first direction x and the first direction is close to 90°, which may be within a range of 80° to 100°, and a person skilled in the art does not limit the state to be completely perpendicular.

The substrate 1 may be a rigid substrate made of glass or quartz, or a flexible substrate made of a polymer material such as polyimide (PI), polycarbonate (PC), polyethylene terephthalate (PET), polyethylene naphthalate (PEN), or graphite.

One of the first electrode 2 or the second electrode 10 is formed of a translucent electrode, while the other one of the first electrode 2 or the second electrode 10 is formed of a reflective electrode. In the case where the first electrode 2 is a translucent electrode and the second electrode 10 is a reflective electrode, the OLED device is configured with a backward light-emitting structure that emits light downward. In the case where the second electrode 10 is a translucent electrode and the first electrode 2 is a reflective electrode, the OLED device is configured with a forward light-emitting structure that emits light upward. In the present application, a description is given by taking the case where the first electrode 2 is an anode formed of a reflective electrode and the second electrode 10 is a cathode formed of a translucent electrode as an example.

The first electrode 2 is configured with a multi-layer structure, including a metal layer formed of aluminum (Al) or an aluminum alloy (e.g., AlNd), and a transparent layer formed of indium tin oxide (ITO) or indium zinc oxide (IZO). The first electrode 2 functions as a reflective electrode. The second electrode 10 is configured with a single-layer structure or a multi-layer structure. Each layer constituting the second electrode 10 may be formed of a metal, an inorganic substance, a metal mixture, a metal and inorganic substance mixture, or a mixture thereof. In the case where each layer is formed of a metal and inorganic substance mixture, a ratio of the metal to the inorganic substance is 10:1 to 1:10. In the case where each layer is formed of a metal mixture, a mixing ratio of one metal to the other metal is 10:1 to 1:10. The second electrode 10 is formed of a metal (e.g., Ag, Mg, Yb, Li, or Ca). The second electrode 10 is formed of an inorganic substance LiO₂, CaO, LiF, or MgF₂. The second electrode 10 facilitates movement of electrons so that a large number of electrons are supplied to the light-emitting layer 6.

As shown in FIG. 2, the light-emitting layer 6 includes a first light-emitting region 6a, a second light-emitting region 6b and a third light-emitting region 6c, which are arranged in a second direction y and emit different colors of light. The first hole transport layer 5 includes a first hole transport region 5ab opposite to the first light-emitting region 6a and the second light-emitting region 6b, and a second hole transport region 5c opposite to the third light-emitting region 6c. The first hole transport region 5ab of the first hole transport layer 5 is formed of a hole matrix and a first p-type doping material.

In this embodiment, regions of the display panel corresponding to the first light-emitting region 6a and the second light-emitting region 6b are p-type doped, while the remaining regions are not doped, so that the overall capacitance of the first light-emitting region 6a and the second light-emitting region 6b can be adjusted to keep the capacitance 6b of the first light-emitting region and the capacitance of the second light-emitting region 6a in the light-emitting layer 6 at the same level, thereby alleviating the problem of the color cast of the display panel after reliability testing.

Compared with the related art (as shown in FIG. 1) in which the first light-emitting region 6a, the second light-emitting region 6b and the third light-emitting region 6c respectively correspond to regions of a first original hole transport region 5a′, a second original hole transport region 5b′ and a third original hole transport region 5c′ made of different materials in the first original hole transport layer 5′, as shown in FIG. 2, in this embodiment, mixed p-type doping is performed on the hole transport region 5ab corresponding to both the first light-emitting region 6a and the second light-emitting region 6b, to ensure that the first light-emitting layer 6 and the second light-emitting layer 6 have the same the doping concentration of p-type doping, and thus the capacitances of the first light-emitting layer 6 and the second light-emitting layer 6 are kept at the same level, thereby reducing the use of a mask and simplifying the manufacturing process through the mixed doping. In addition, a region of the first hole transport layer 5 close to the light-emitting layer 6 can also function to adjust a microcavity for the light-emitting layer 6.

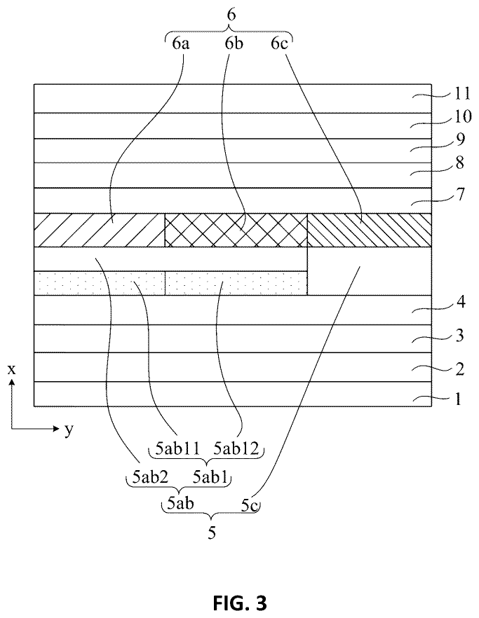

In some embodiments, as shown in FIG. 3, a hole transport region corresponding to the first light-emitting layer 6 and a hole transport region corresponding to the second light-emitting layer 6 may be doped separately, and a first hole transport sub-layer 5ab1 is separated into a first hole transport sub-region 5ab11 and a second hole transport sub-region 5ab12, as long as the two regions have the same doping concentration of p-doping.

In some embodiments, a comparative experiment is performed on the structures shown in FIG. 1 and FIG. 2 under the same conditions, and the test results are shown in FIG. 5, which shows that the greenish condition after reliability testing is significantly improved in the structure of the display panel of the present application.

In some embodiments, a mass percent of the first p-type doping material in the first hole transport region 5ab of the first hole transport layer 5 is greater than or equal to 0.1% and less than or equal to 1%.

In this embodiment, the doping concentration of the first p-type doping material in the first hole transport region 5ab of the first hole transport layer 5 is controlled to enable substantially the same capacitance level in the first light-emitting region 6a and the second light-emitting region 6b in the display panel, so that the color rendering is controlled to be uniform, and the color cast problem caused by different capacitances can be improved.

In some embodiments, as shown in FIG. 2, the first hole transport region 5ab of the first hole transport layer 5 includes a first hole transport sub-layer 5ab1 and a second hole transport sub-layer 5ab2 sequentially stacked in the first direction x, where the first hole transport sub-layer 5ab1 is formed of the hole matrix and the first p-type doping material; and the second hole transport sub-layer 5ab2 is formed of the hole matrix.

In the present application, a region of the first hole transport region 5ab adjacent to the light-emitting layer 6 forms the second hole transport sub-layer 5ab2, and the second hole transport sub-layer 5ab2 is formed of the hole matrix, so that the influence on the light-emitting efficiency of the light-emitting layer 6 when p doping is introduced into the first hole transport layer 5 can be avoided. The display effect is further improved.

In some embodiments, as shown in FIG. 2, a ratio of a thickness of the first hole transport sub-layer 5ab1 in the first direction x to a thickness of the second hole transport sub-layer 5ab2 in the first direction x is in a range of 1:3 to 1:10.

In this embodiment, the relationship between the thickness of the first hole transport sub-layer 5ab1 and the thickness of the second hole transport sub-layer 5ab2 is further defined so that by adjusting the thicknesses and the ratios of the first hole transport sub-layer 5ab1 and the second hole transport sub-layer 5ab2, the hole transport layers can fall into an interval which is most beneficial to adjusting the color cast problem, and the first light-emitting layer 6 and the second light-emitting layer 6 can be enabled to emit the same color of light through p-type doping without affecting the light-emitting effect of the light-emitting layer 6 in the display panel.

In some embodiments, as shown in FIG. 2, the first hole transport sub-layer 5ab1 has a thickness of 50 Å to 100 Å, and the second hole transport sub-layer 5ab2 has a thickness of 300 Å to 500 Å.

In some embodiments, as shown in FIG. 2, the display panel further includes a second hole transport layer 4 on a side of the first hole transport layer 5 away from the light-emitting layer 6; and a ratio of a thickness of the first hole transport layer 5 in the first direction x to a thickness of the second hole transport layer 4 in the first direction x is in a range of 1:1 to 1:4.

This embodiment is further provided with a second hole transport layer 4, which is a common hole transport layer of the first light-emitting layer 6, the second light-emitting layer 6 and the third light-emitting layer 6, configured for the overall hole transport of the light-emitting layer 6, and, by defining a relationship between the thickness of the first hole transport layer 5 and the thickness of the second hole transport layer 4, configured to recombine the electrons and the holes successfully to generate excitons and release energy, so that the luminescent material in the light-emitting layer 6 can successfully emit light.

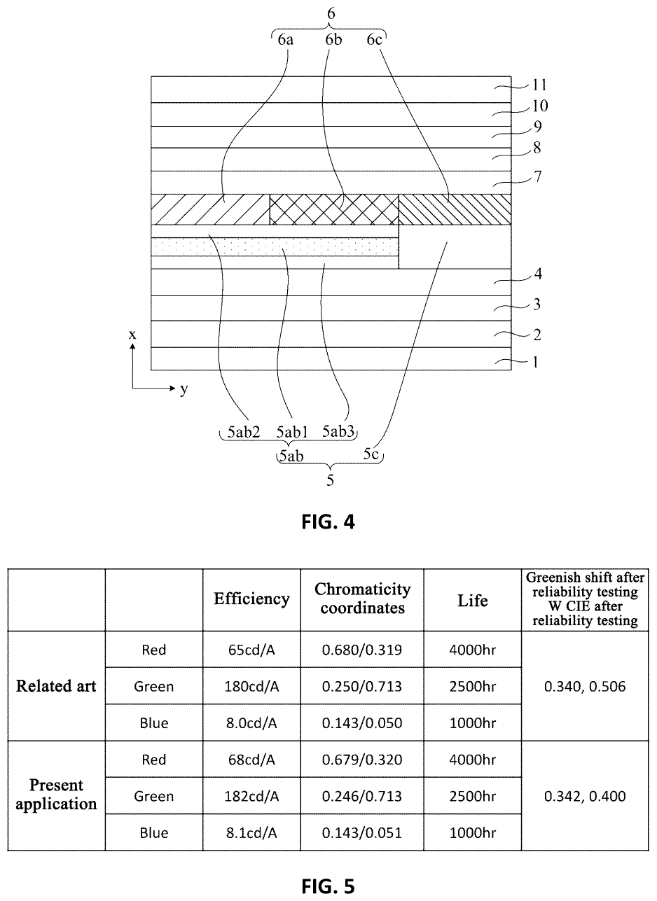

In some embodiments, as shown in FIG. 4, the first hole transport layer 5 further includes a third hole transport sub-layer 5ab3 on a side of the first hole transport sub-layer 5ab1 close to the substrate 1. The third hole transport sub-layer 5ab3 is formed of the hole matrix, and configured to assist hole transport.

In some embodiments, as shown in FIG. 2, wavelengths of light emitted from the first light-emitting region 6a, the second light-emitting region 6b, and the third light-emitting region 6c sequentially decrease. In the first direction x, thicknesses of the first light-emitting region 6a, the second light-emitting region 6b and the third light-emitting region 6c of the light-emitting layer 6 sequentially decrease.

Specifically, in some embodiments, as shown in FIG. 2, the first light-emitting region 6a emits red light, the second light-emitting region 6b emits green light, and the third light-emitting region 6c emits blue light. In the first direction x, the first light-emitting region 6a has a thickness of 400 Å to 500 Å, the second light-emitting region 6b has a thickness of 300 Å to 400 Å, and the third light-emitting region 6c has a thickness of 200 Å to 300 Å.

It should be noted that, in some embodiments, the first light-emitting region 6a emits green light, and the second light-emitting region 6b emits red light, so that when both the first light-emitting region 6a and the second light-emitting region 6b perform p-doping on the hole transport region, the capacitance of the red light is leveled with the capacitance of the green light to improve the color cast. Specifically, settings may be made by a person skilled in the art according to the pixel arrangement mode, and are not limited thereto.

In some embodiments, as shown in FIG. 2, a hole injection layer 3, formed of the hole matrix and a second p-type doping material, is further provided on a side of the first electrode 2 away from the substrate 1.

In this embodiment, a hole injection layer 3 is further provided on a side of the first electrode 2 away from the substrate 1, through which excitons can be formed in the light-emitting layer 6 instead of an interface between the electron transport layer 8 and the light-emitting layer 6, so that the display efficiency can be improved, and the service life of the display panel can be extended.

In some embodiments, a mass percent of the second p-type doping material in the hole injection layer 3 is greater than or equal to 1% and less than or equal to 10%.

In this embodiment, by providing the doping concentration of the second p-type doping material in the hole injection layer 3 higher than the doping concentration of the first p-type doping material in the first hole transport layer 5, electrons and holes in the display panel can form excitons in the light-emitting layer 6 under the driving of current, thereby realizing light emission.

In some embodiments, the first p-type doping material includes 2,3,5,6-tetrafluoro-7,7′,8,8′-tetracyanodimethyl-p-benzoquinone (F4TCNQ), 2,3,6,7,10,11-hexacyano-1,4,5,8,9,12-hexaazatriphenylene (HATCN) or pyrazolo[2,3-F][1,10]phenanthroline-2,3-dinitrile (PPDN). Specifically, the chemical structural formulas of F4TCNQ, HATCN and PPDN are:

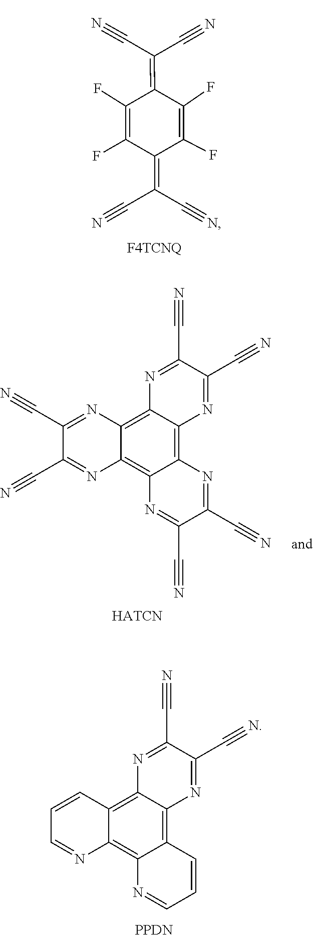

In some embodiments, the second p-type doping material is the same as the first p-type doping material.

The hole matrix includes N,N′-diphenyl-N,N′-(1-naphthyl)-1,1′-biphenyl-4,4′-diamine (NPB), N,N′-diphenyl-N,N′-bis(3-methylphenyl)-[1,1′-biphenyl]-4,4′-diamine (TPD), 4,4′,4″-tris(carbazole-9-yl)triphenylamine (TCTA), or 4-[1-[4-[bis(4-methylphenyl)amino]phenyl]cyclohexyl]-N-(3-methylphenyl)-N-(4-methylphenyl) aniline (TAPC). Specifically, the chemical structural formulas of NPB, TPD, TCTA and TAPC are:

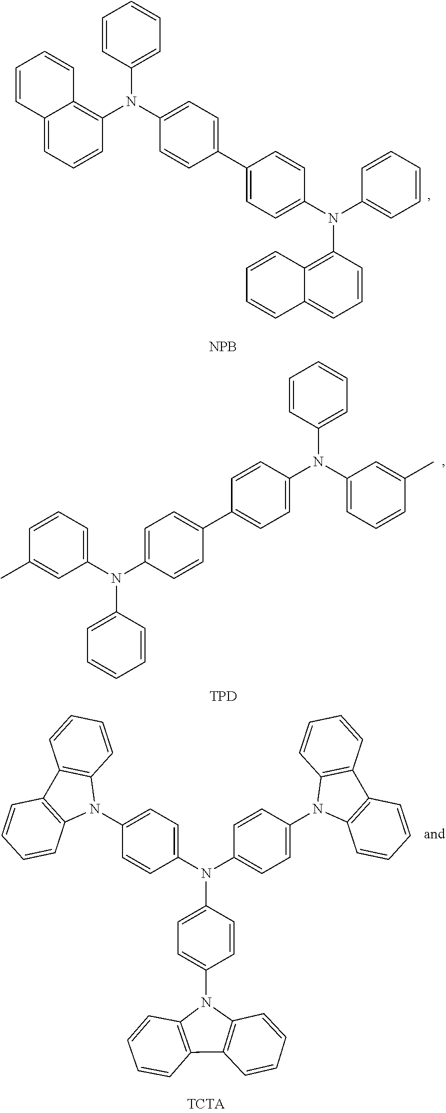

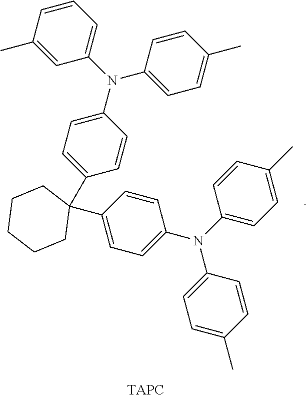

In some embodiments, as shown in FIG. 2, a hole blocking layer 7, an electron transport layer 8, and an electron injection layer 9 are further sequentially stacked in the first direction x between the light-emitting layer 6 and the second electrode 10, and an encapsulation layer 11 is further provided on a side of the second electrode 10 away from the light-emitting layer 6. In the first direction x, the hole blocking layer 7 has a thickness of 50 Å to 100 Å, the electron transport layer 8 has a thickness of 200 Å to 300 Å, the second electrode 10 has a thickness of 100 Å to 150 Å, and the encapsulation layer 11 has a thickness of 700 Å to 900 Å.

In some embodiments, the hole blocking layer 7, the electron transport layer 8, and the electron injection layer 9 may be made of an aromatic heterocyclic compound, such as 2,2′-(1,3-phenyl)bis[5-(4-tert-butylphenyl)-1,3,4-oxadiazole] (OXD-7), 3-(biphenyl-4-yl)-5-(4-tert-butylphenyl)-4-phenyl-4H-1,2,4-triazole (TAZ), 4,7-diphenyl-1,10-phenanthroline (Bphen), or 1,3,5-tris(N-phenylbenzimidazol-2-yl)benzene (TPBi). Specifically, the chemical structural formulas of OXD-7, TAZ, BPhen, and TPBi are:

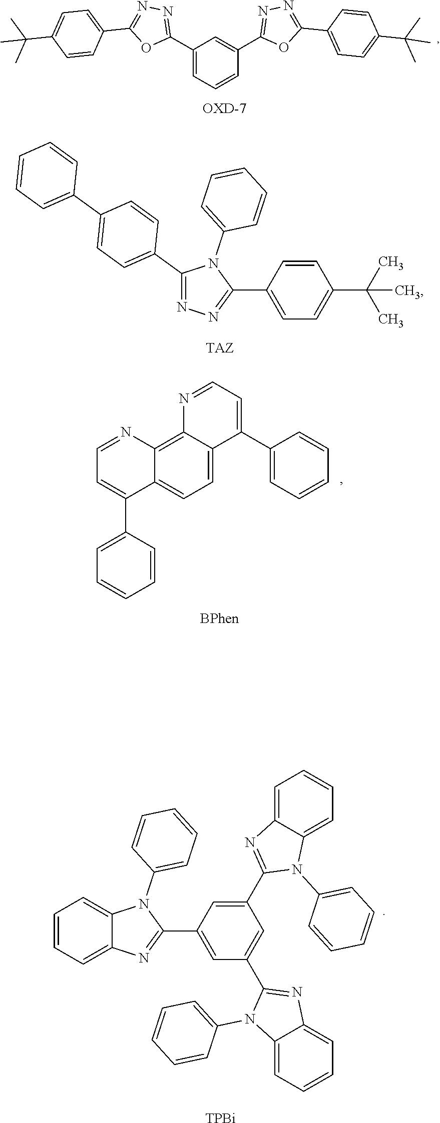

In some embodiments, the encapsulation layer 11 includes a first inorganic encapsulation layer, an organic encapsulation layer, and a second inorganic encapsulation layer sequentially stacked in the first direction x to protect the display panel from moisture.

The present application further provides a display device, including the display panel according to any embodiment described above. The display device has the advantages of the display panel in the foregoing embodiments, which are not repeated here.

It should be noted that the display device may be any device that can display texts or images, whether moving (e.g., videos) or stationary (e.g., still images). More specifically, it is contemplated that the embodiments may be implemented in or associated with a variety of electronic devices, such as, but not limited to, mobile telephones, wireless devices, personal data assistants (PDAs), handheld or portable computers, GPS receivers/navigators, cameras, MP4 video players, camcorders, game consoles, watches, clocks, calculators, television monitors, tablet displays, computer monitors, automotive displays (e.g., odometer displays, etc.), navigators, cockpit controllers and/or displays, camera view displays (e.g., displays for rearview cameras in vehicles), electronic photographs, electronic billboards or signs, projectors, architectural structures, packages, and aesthetic structures (e.g., an image display for a piece of jewelry), and the like.

The above embodiments of the present application may complement each other without conflict.

It should be noted that in the drawings, sizes of the layers and areas may be exaggerated for clarity of illustration. Moreover, it will be understood that when an element or layer is referred to as being “on” another element or layer, it may be directly on the other element or layer, or intervening layers may be present. In addition, it will be understood that when an element or layer is referred to as being “under” another element or layer, it may be directly under the other element or more than one intervening layer or element may be present. In addition, it will be further understood that when a layer or element is referred to as being “between” two layers or elements, it may be the only layer between the two layers or elements, or more than one intervening layer or element may be present. Like reference numerals refer to like elements throughout the disclosure.

The terms “central”, “upper”, “lower”, “front”, “rear”, “left”, “right”, “vertical”, “horizontal”, “top”, “bottom”, “inner”, “outer”, and the like are based on the orientations or positional relationships shown in the drawings, and are merely for the purposes of describing the present application and simplifying the description, instead of indicting or implying that the device or component referred to must have a specific orientation or be configured or operated at a specific orientation, and thus should not be interpreted as limitations to the present application.

The terms “first”, “second” are used for the purpose of illustration only and are not to be construed as indicating or implying a relative importance or implicitly indicating the number of the indicated technical features. Therefore, a feature defined by “first” or “second” may include one or more of the indicated features either explicitly or implicitly. In the description of the present application, “a plurality” means two or more unless otherwise specified.

Other implementations of the present application will be apparent to those skilled in the art from consideration of the description and practice of the present disclosure disclosed herein. The present application is intended to cover any variations, uses, or adaptations of the present application which follow general principles of the present application and include common knowledge or conventional technical means in the art that are not disclosed herein. The description and the embodiments are intended to be considered as exemplary only, with a true scope and spirit of the present application being indicated by the claims.

It will be appreciated that the present application is not limited to the precise structures as described above and shown in the drawings, and that various modifications and changes may be made without departing from the scope of the present disclosure. The scope of the present application is defined only by the appended claims.

1. A display panel, comprising a first electrode, a first hole transport layer, a light-emitting layer, and a second electrode which are sequentially stacked on a substrate in a first direction, wherein the first direction is a direction pointing to the second electrode from the first electrode, and a second direction is perpendicular to the first direction; wherein the light-emitting layer comprises a first light-emitting region, a second light-emitting region and a third light-emitting region, which are arranged in the second direction and emit different colors of light; and
the first hole transport layer comprises a first hole transport region opposite to the first light-emitting region and the second light-emitting region, and a second hole transport region opposite to the third light-emitting region; and the first hole transport region of the first hole transport layer is formed of a hole matrix and a first p-type doping material.

2. The display panel according to claim 1, wherein a mass percent of the first p-type doping material in the first hole transport region of the first hole transport layer is greater than or equal to 0.1% and less than or equal to 1%.

3. The display panel according to claim 1, wherein the first hole transport region of the first hole transport layer comprises a first hole transport sub-layer and a second hole transport sub-layer sequentially stacked in the first direction, wherein
the first hole transport sub-layer is formed of the hole matrix and the first p-type doping material; and
the second hole transport sub-layer is formed of the hole matrix.

4. The display panel according to claim 3, wherein a ratio of a thickness of the first hole transport sub-layer in the first direction to a thickness of the second hole transport sub-layer in the first direction is in a range of 1:3 to 1:10.

5. The display panel according to claim 3, wherein the display panel further comprises a second hole transport layer on a side of the first hole transport layer away from the light-emitting layer; and
a ratio of a thickness of the first hole transport layer in the first direction to a thickness of the second hole transport layer in the first direction is in a range of 1:1 to 1:4.

6. The display panel according to claim 1, wherein wavelengths of light emitted from the first light-emitting region, the second light-emitting region, and the third light-emitting region sequentially decrease; and
in the first direction, thicknesses of the first light-emitting region, the second light-emitting region and the third light-emitting region of the light-emitting layer sequentially decrease.

7. The display panel according to claim 1, wherein a hole injection layer, formed of the hole matrix and a second p-type doping material, is further provided on a side of the first electrode away from the substrate.

8. The display panel according to claim 7, wherein a mass percent of the second p-type doping material in the hole injection layer is greater than or equal to 1% and less than or equal to 10%.

9. The display panel according to claim 1, wherein the first p-type doping material comprises 2,3,5,6-tetrafluoro-7,7′,8,8′-tetracyanodimethyl-p-benzoquinone, 2,3,6,7,10,11-hexacyano-1,4,5,8,9,12-hexaazatriphenylene, or pyrazolo[2,3-F][1,10] phenanthroline-2,3-dinitrile.

10. The display panel according to claim 1, wherein the hole matrix comprises N,N′-diphenyl-N,N′-(1-naphthyl)-1,1′-biphenyl-4,4′-diamine, N,N′-diphenyl-N,N′-bis(3-methylphenyl)-[1,1′-biphenyl]-4,4′-diamine, 4,4′,4″-tris(carbazole-9-yl)triphenylamine (TCTA), or 4-[1-[4-[bis(4-methylphenyl)amino]phenyl]cyclohexyl]-N-(3-methylphenyl)-N-(4-methylphenyl) aniline.

11. A display device, comprising the display panel according to claim 1.

12. A display device, comprising the display panel according to claim 2.

13. A display device, comprising the display panel according to claim 3.

14. A display device, comprising the display panel according to claim 4.

15. A display device, comprising the display panel according to claim 5.

16. A display device, comprising the display panel according to claim 6.

17. A display device, comprising the display panel according to claim 7.

18. A display device, comprising the display panel according to claim 8.

19. A display device, comprising the display panel according to claim 9.

20. A display device, comprising the display panel according to claim 10.
